(19) United States
(12) Patent Application Publication
(10) Pub. No.: US 2009/0152415 A1
(43) Pub. Date: Jun. 18, 2009

(54) APPARATUS FOR HOLDING HARD DISK DRIVE

(75) Inventors: Shin-Hsun YANG, Taipei City (TW); Te-Sheng Liu, Taichung City (TW); Chih-Pin Chen, Taipei City (TW); Kuo-Kuang Liu, Nantou County (TW)

Correspondence Address: BROWDY AND NEIMARK, P.L.L.C.;624 NINTH STREET, NW, SUITE 300, WASHINGTON, DC, 20001-5303, US

(73) Assignee: UNIVERSAL SCIENTIFIC INDUSTRIAL CO., LTD., Tsao Tuen (TW)

(21) Appl. No.: 12/119,634

(22) Filed: May 13, 2008

(30) Foreign Application Priority Data
Dec. 13, 2007 (TW) 96221238

(51) Int. Cl. A47B 96/06; G06F 1/16; H05K 5/00; H05K 7/00

(52) U.S. Cl. 248/201

(57) ABSTRACT

An apparatus includes a first bracket and a second bracket detachably receivable in the first bracket for holding a hard disk drive therein. The first bracket has a first coupling portion with a block, and a second coupling portion with a groove. The second bracket has a third coupling portion with a slot detachably receivable with the block of the first bracket, and a fourth coupling portion with a pivotable positioning rod member detachably engageable into the groove of the first bracket. Disengaging the slot and the pivotable positioning rod of the second bracket from the block and the groove of the first bracket allows dismounting of the second bracket from the first bracket without using any tools.

### BACKGROUND OF THE INVENTION

1. Field of the Invention

The present invention relates generally to hard disk drive mounting equipments and more specifically, to an apparatus for holding hard disk drive, which allows mounting and dismounting of the hard disk drive rapidly without using any tools.

2. Description of the Related Art

Conventionally, a hard disk drive is installed in a computer case by a holding box which accommodates the hard disk drive therein. During installation, the hard disk drive is affixed to the holding box with screws in advance, and then the holding box is mounted inside the computer case. When wanting to remove the hard disk drive from the computer case, the user must remove the holding box from the computer case.

During a maintenance work, the user must use a screwdriver to unfasten the screws from the hard disk drive and the holding box for enabling separation of the hard disk drive from the holding box. After the maintenance work is done, the user has to insert the hard disk drive into the holding box and then use the screwdriver and screws to screwingly affix the hard disk drive to the holding box in position. This mounting and dismounting procedure is time-consuming and inconvenient.

### SUMMARY OF THE INVENTION

The present invention has been accomplished in view of the above-noted circumstances. It is therefore one objective of the present invention to provide an apparatus for holding a hard disk drive therein, which facilitates mounting and dismounting of the hard disk drive without using any tools.

To achieve this objective of the present invention, the apparatus provided by the present invention comprises a first bracket and a second bracket detachably receivable in the first bracket for holding detachably a hard disk drive therein. The first bracket comprises at least one first coupling portion, and at least one second coupling portion. The second bracket comprises at least one third coupling portion detachably couplable to the first coupling portion of the first bracket, and at least one fourth coupling portion detachably couplable to the second coupling portion of the first bracket.

When a user wants to remove the hard disk drive, the removal can be done by disengaging the third coupling portion and the fourth coupling portion of the second bracket from the first coupling portion and the second coupling portion of the first bracket, and then detaching the hard disk drive from the second bracket without using any tools.

In a preferred embodiment of the present invention to be detailed described hereinafter, the first coupling portion of the first bracket is embodied as a block, and the third coupling portion of the second bracket is embodied as a slot for retaining the block. The slot may preferably include a vertical section and a horizontal section in communication with the vertical section, such that the block can be vertically inserted into the vertical section and moved into and retained at the horizontal section of the slot.

Preferably, the second bracket is provided at each of two opposite sidewalls thereof with a locating rod for detachably inserting into a locating hole provided at each of two opposite sidewalls of the hard disk drive, such that the hard disk drive can be quickly and conveniently engaged with and detached from the second bracket without using any tools.

In the preferred embodiment of the present invention, the second coupling portion of the first bracket is embodied as a groove, and the fourth coupling portion of the second bracket is embodied as a positioning rod member for engagement with the groove. Preferably, the positioning rod member is pivotally provided at the second bracket.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below and the accompanying drawings which are given by way of illustration only, and thus are not limitative of the present invention, and wherein:

FIG. 1 is an exploded view of an apparatus for holding hard disk drive in accordance with a preferred embodiment of the present invention;

FIG. 2 is a schematic drawing showing that a hard disk drive is received inside the second bracket;

FIG. 3 is a schematic drawing showing that the second bracket carrying the hard disk drive is placed in the first bracket, wherein the blocks of the first bracket are respectively received in the vertical sections of the slots of the second bracket;

FIG. 4 is similar to FIG. 3, but showing that the blocks of the first bracket are respectively moved into and retained at the horizontal sections of the slots of the second bracket, and

FIG. 5 is a schematic and partial cutaway view of the apparatus for holding hard disk drive of the present invention, showing that the positioning rod member of the second bracket is engaged into the groove of the first bracket.

### DETAILED DESCRIPTION OF THE INVENTION

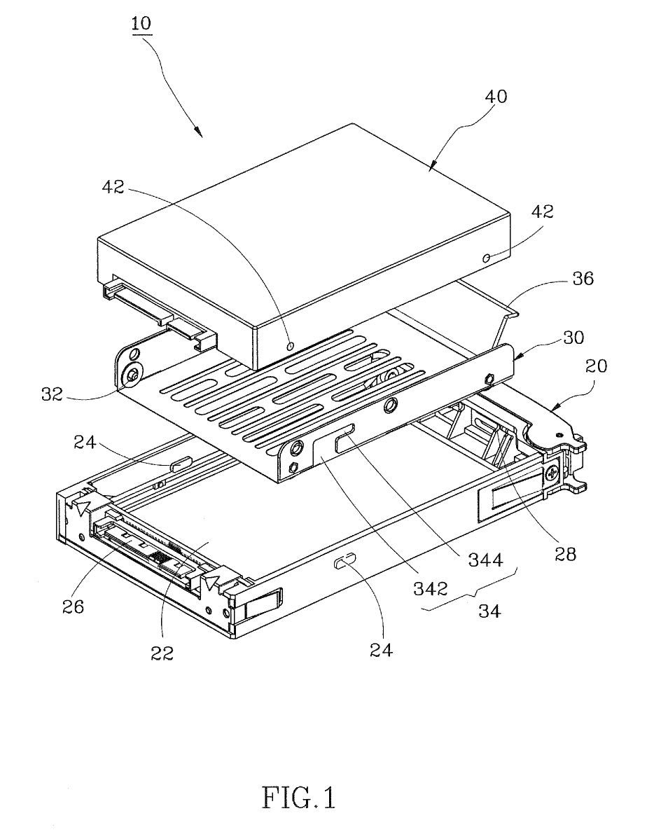

As shown in FIGS. 1-5, an apparatus 10 for holding a hard disk drive, referenced by 40, in accordance with a preferred embodiment of the present invention comprises a first bracket 20 and a second bracket 30.

The first bracket 20 is substantially a rectangular frame member having a top-opened accommodation chamber 22, a first coupling portion 24, which is embodied as a block in this embodiment, provided at each of the inner surfaces of the two opposite lateral sidewalls thereof and suspended in the top-opened accommodation chamber 22, a circuit board 26 provided at one end thereof, and a second coupling portion 28, which is embodied as a groove in this embodiment, at the other end thereof.

The second bracket 30 is configured in size and shape to be fittable with the top-opened accommodation chamber 22 so that the second bracket 30 is receivable within the top-opened accommodation chamber 22 of the first bracket 20. The second bracket 30 has two locating rods 32 respectively extending from the inner surfaces of the two opposite sidewalls thereof, two third coupling portions 34 respectively provided at the two opposite sidewalls for coupling to the first coupling portions 24 of the first bracket 20, and a fourth coupling portion 36 disposed at the rear end for engagement with the second coupling portion 28 of the first bracket 20. According to this embodiment, the two third coupling portions 34 are embodied as slots each having a vertical section 342 and a horizontal section 344 extending from the top end of the vertical section 342 at right angles. The vertical section 342 has a transverse width slightly greater than the transverse width of the first coupling portions 24 of the first bracket 20, and a vertical height greater than the vertical height of the first coupling portions 24 of the first bracket 20 so that each first coupling portion 24 of the first bracket 20 is vertically movable along the vertical section 342 of the associated third coupling portion 34 and prohibited from transverse displacement relative to vertical section 342 of the associated third coupling portion 34. In addition, the horizontal section 344 has a transverse width greater than the transverse width of the first coupling portions 24 of the first bracket 20, and a vertical height slightly greater than the vertical height of the first coupling portions 24 of the first bracket 20 so that each first coupling portion 24 of the first bracket 20 is horizontally movable along the horizontal section 344 of the associated third coupling portion 34 and prohibited from vertical displacement relative to horizontal section 344 of the associated third coupling portion 34. Further, the fourth coupling portion 36 according to this embodiment is embodied as a positioning rod member pivoted to the second bracket 30 for engaging into the second coupling portion (groove) 28 of the first bracket 20, as shown in FIG. 5.

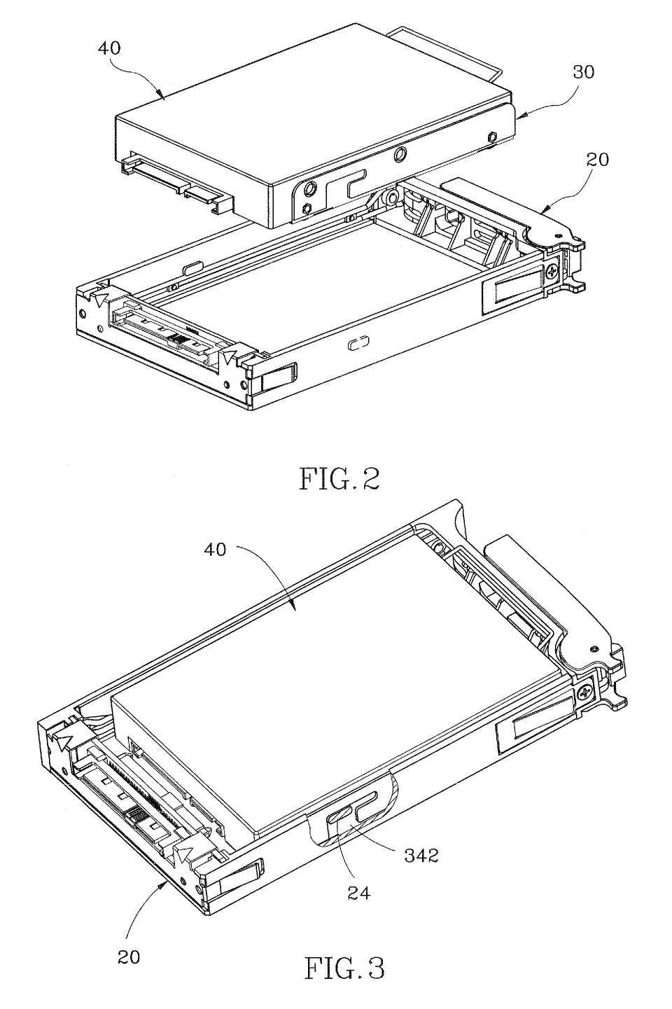

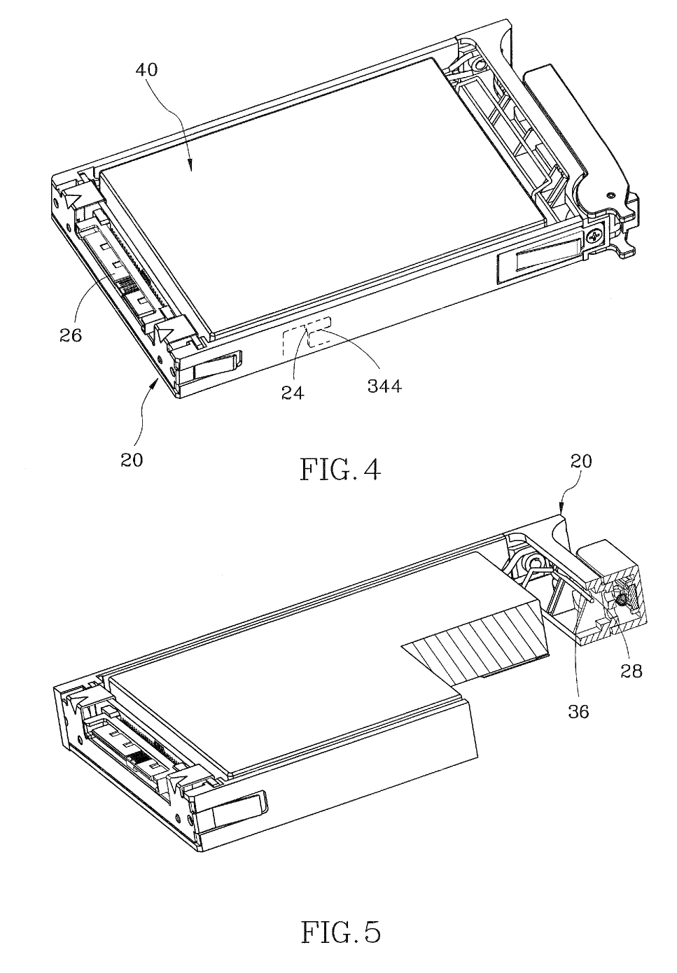

During installation of the hard disk drive 40, the two opposite sidewalls of the second bracket 30 can be slightly pulled outwards for enabling the locating rods 32 to be respectively engaged into one respective locating hole 42 at each of the two opposite lateral sidewalls of the hard disk drive 40. After loading of the hard disk drive 40 to the inside of the second bracket 30 as shown in FIG. 2, the vertical sections 342 of the third coupling portions 34 of the second bracket 30 are respectively coupled to the first coupling portions (blocks) 24 of the first bracket 20 to have the hard disk drive 40 be received with the second bracket 20 inside the first bracket 10. When the first coupling portions (blocks) 24 of the first bracket 20 respectively touch the respective top ends of the respective vertical sections 342 of the third coupling portions 34 of the second bracket 30, as shown in FIG. 3, the hard disk drive 40 and the second bracket 30 are fully received inside the first bracket 20. At this time, the user can move the hard disk drive 40 with the second bracket 30 relative to the first bracket 20 in one direction toward the circuit board 26, thereby forcing the first coupling portions (blocks) 24 of the first bracket 20 into the horizontal sections 344 of the third coupling portions 34 of the second bracket 30, as shown in FIG. 4. When the hard disk drive 40 is forced into electric connection with the circuit board 26, the fourth coupling portion (positioning rod member) 36 of the second bracket 30 can be forced into engagement with the second coupling portion (groove) 28 of the first bracket 20, as shown in FIG. 5, and therefore, the hard disk drive 40 with the second bracket 30 are firmly secured to the inside of the top-opened accommodation chamber 22 of the first bracket 20.

When the user wants to dismount the hard disk drive 40, the user can disengage the fourth coupling portion (positioning rod member) 36 of the second bracket 30 from the second coupling portion (groove) 28 of the first bracket 20, thereafter move the hard disk drive 40 with the second bracket 30 relative to the first bracket 20 in direction apart from the circuit board 26 to have the first coupling portions (blocks) 24 of the first bracket 20 be shifted to the vertical sections 342 of the third coupling portions 34 of the second bracket 30 for allowing removal of the hard disk drive 40 with the second bracket 30 from the top-opened accommodation chamber 22 of the first bracket 20, and then pull the two opposite sidewalls of the second bracket 30 to disengage the locating rods 32 from respective locating holes 42 of the hard disk drive 40, thereby allowing removal of the hard disk drive 40 from the second bracket 30.

As stated above, by means of the good match between the first coupling portions (blocks) 24 of the first bracket 20 and the vertical sections 342 of the third coupling portions 34 of the second bracket 30, the hard disk drive 40 and the second bracket 30 can only be moved in vertical direction into the inside of the top-opened accommodation chamber 22 of the first bracket 20. By means of the good match between the first coupling portions (blocks) 24 of the first bracket 20 and the horizontal sections 344 of the third coupling portions 34 of the second bracket 30, the hard disk drive 40 and the second bracket 30 can be moved horizontally relative to the first bracket 20 to force the hard disk drive 40 into electric connection with the circuit board 26 and to prohibit vertical displacement of the hard disk drive 40 with the second bracket 30 relative to the first bracket 20, i.e., to prohibit removal of the hard disk drive 40 with the second bracket 30 from the top-opened accommodation chamber 22 of the first bracket 20. When the user wants to dismount the hard disk drive 40, the user can simply reverse the loading procedure without using any tools.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. An apparatus for holding a hard disk drive comprising:
a first bracket having at least one first coupling portion and at least one second coupling portion; and
a second bracket detachably receivable in said first bracket for holding detachably the had disk drive therein, said second bracket having at least one third coupling portion detachably couplable to the first coupling portion of said first bracket, and at least one fourth coupling portion detachably couplable to the second coupling portion of said first bracket.

2. The apparatus as claimed in claim 1, wherein said first coupling portion of said first bracket comprises a block; said third coupling portion of said second bracket comprises a slot for retaining said block.

3. The apparatus as claimed in claim 2, wherein said slot includes a vertical section and a horizontal section in communication with the vertical section; the block is vertically insertable into the vertical section of said slot and movable from the vertical section into the horizontal section of said slot.

4. The apparatus as claimed in claim 1, wherein second bracket has two opposite sidewalls from each of which at least one locating rod extends for inserting into at least one locating hole provided at two opposite lateral sidewalls of the hard disk drive.

5. The apparatus as claimed in claim 1, wherein said second coupling portion of said first bracket comprises a groove; said fourth coupling portion of said second bracket comprises a positioning rod member for engaging the groove.

6. The apparatus as claimed in claim 5, wherein the positioning rod member is pivotally provided at said second bracket.
